(19) United States
(12) Patent Application Publication
(10) Pub. No.: US 2021/0203352 A1
(43) Pub. Date: Jul. 1, 2021

(54) METHOD OF CODING BASED ON TRANSITION OF LASING AND NON-LASING STATES OF OPTICAL STRUCTURE

(71) Applicant: East China Normal University, Shanghai (CN)

(72) Inventors: Wei XIE, Shanghai (CN); Meng FEI, Shanghai (CN); Hongxing DONG, Shanghai (CN); Yichi ZHONG, Shanghai (CN)

(21) Appl. No.: 17/125,063

(22) Filed: Dec. 17, 2020

(30) Foreign Application Priority Data
Dec. 25, 2019 (CN) 201911352540.5

(51) Int. Cl. H03M 7/00; G02B 27/10; G02F 1/35; G02F 1/37; G01N 21/63

(52) U.S. Cl. CPC H03M 7/008; G02B 27/106; G01N 21/63; G02F 1/37; G02F 1/3526

(57) ABSTRACT

A method of coding based on transition of lasing and non-lasing states of an optical structure. The power of a single pulse within picosecond-scale time is regulated to achieve transition of lasing and non-lasing states of an optical structure capable of emitting light and having the characteristic of resonant cavity and high Q value along a light path created by a combination of optical elements such as beam splitters, adjustable reflectors and continuously adjustable attenuators. Due to different parameters carried by light radiation in the two states, the parameters correspond to “1” and “0”, respectively. Therefore, binary high-bandwidth coding is realized, and even ternary coding can be realized with a slight improvement on the basis of the light path of binary coding. The tunable bandwidth of coding may reach up to 0.1 THz, which is conducive to promoting the development of high-bandwidth information processing optical microchips.

### RELATED APPLICATION

This application claims priority under 35 U.S.C. 119(a)-(d) to Foreign Application No. 201911352540.5 entitled “METHOD OF CODING BASED ON TRANSITION OF LASING AND NON-LASING STATES OF OPTICAL STRUCTURE” and filed in China on Dec. 25, 2019, the contents of which are herein incorporated in their entirely by reference for all purposes.

### TECHNICAL FIELD

The present disclosure belongs to the technical field of photoelectric materials and devices, and in particular, relates to a method of high-bandwidth coding based on transition of lasing and non-lasing states of an optical structure.

### BACKGROUND

In recent years, nanometer-scale microstructures can already be achieved with the advances in growth technology and precision machining technology, and materials including micron-scale and sub-micron-scale fine structures are collectively referred to as micro-nano materials. Hence, optics can be studied by being integrated into microstructures instead of a large optical platform. Accordingly, more methods and tools to regulate electromagnetic waves may be provided, allowing for more abundant research in numerous fields, such as laser physics and non-linear optics. When excited by laser, a microstructure may often produce unusual effects (e.g., optical waveguide and optical cavity) because of change to its size and shape. Much information may be generated or original optical information may be converted in this process. Therefore, there have been a wide range of research on information coding based on the fluorescence lifetime, intensity or peak position of a microstructure. There have been a lot of reports about coding by later passive modulation of optical signals based on light output by an existing light source, but almost no report about direct coding using a miniature laser device capable of lasing.

With the rapid development of the ultrafast pulse laser technology, it is possible to realize femtosecond-scale time of relaxation for pulses, so that ultrashort pulses can be used as important means to explore ultrafast processes in the fields of physics, biology, chemistry, etc. High-rate high-bandwidth optical coding using femtosecond-scale pulse laser is being extensively studied now, in which terahertz or even above tunable coding bandwidth can be achieved. This means that a larger volume of data can be transmitted simultaneously. Hence, it is of practical significance to study how to code using ultrafast pulse laser in the field of optical communications.

Most of existing methods, however, have the disadvantage of later passive modulation of optical signals based on light output by their existing light sources. The properties of base light cannot be changed under passive modulation, and the fidelity of coding completely relies on the accuracy of modulation means. Moreover, the base light is necessary no matter whether the code value is “1” or “0” in passive modulation, which goes against energy saving.

### SUMMARY

The present disclosure provides a method of high-bandwidth coding based on transition of lasing and non-lasing states of an optical structure for adapting to the development of the times of increasingly miniaturized and wider band coding technology. The method permits active modulation of a laser source, thereby reducing energy consumption in coding and providing a large coding bandwidth.

A specific technical solution is described below.

A method of coding based on transition of lasing and non-lasing states of an optical structure includes the following steps:

step 1: selecting an optical structure which is a light-emitting material or constituted by parts made of a luminous material and possesses the characteristic of optical resonant cavity, with optical cavity quality factor Q value of at least 100 and unlimited chemical composition of the material, and placing the optical structure on a sample stage;

step 2: along a laser transmission path of a laser device, dividing a beam of overall light pulse into several beams of split light pulses using several beam splitters, setting up adjustable reflectors at positions directly facing exit surfaces of the beam splitters, and adjusting the positions of the reflectors relative to the beam splitters to regulate a time of arrival of each split light pulse at the optical structure and a time interval between different split light pulses;

step 3: placing continuously adjustable attenuators between the beam splitters and the adjustable reflectors, rotating the attenuators to control excitation energy density of each split light pulse arriving at the optical structure to be above or below an optical lasing threshold Pₜₕ of the optical structure, where the optical structure is in the lasing state or the non-lasing state at corresponding excitation energy densities, respectively; and placing frequency doubling crystals along a light path behind a first beam splitter to obtain a wavelength-halved light pulse, where the light path is called a frequency-doubled light path, an original-wavelength light pulse is retained along another light path;

step 4: combining different controllable split light pulses into a beam of light by beam combiners for shining on the optical structure placed on the sample stage through a beam splitter and an objective lens, thereby realizing embedding of optical code information, where an induced radiation light field of the optical structure carries a high-bandwidth coding sequence;

step 5: arranging a lens, a spectrometer and a streak camera at a terminal of the light path to collect light radiation signals within the time of the optical structure being excited by the light pulse, thereby obtaining parameter information, namely luminous intensity I, degree of polarization P and degree of coherence c, in the light radiation signals; and

step 6: defining that one or more of the obtained light radiation signal parameters in the lasing state and the non-lasing state correspond to “1” and “0” of binary coding, respectively, and reading or checking an optical coding sequence generated in this period of light pulse excitation time using the spectrometer and the streak camera.

In step 2, the full width at half maximum of the overall light pulse may be at most τ_{rad}/2, and time parameter τ_{rad} may be the full width at half maximum of the light radiation pulse when the optical structure operates in the lasing state, with adjustable pulse interval time of at least τ_{rad}.

In step 2, the regulating of the time interval between different split light pulses may be to change each split light propagation path to realize time delays of different split light pulses.

In step 3, the optical lasing threshold Pₜₕ may depend on the selected optical structure and have a value of 10⁻⁹ to 1 J/cm².

In step 3, a maximum energy density from the split pulses into the optical structure may at least reach Pₜₕ.

In step 5, the detection time accuracy of the streak camera may be at least ⅓ of the full width at half maximum τ_{rad} of a single light radiation pulse.

In step 5, the luminous intensity I may be directly measured by the spectrometer and the streak camera; the degree of polarization P may be calculated with maximum and minimum luminous intensities obtained by the spectrometer and the streak camera after rotating a polarizer set up along a collection light path according to a formula (Iₘₐₓ−Iₘᵢₙ)/(Iₘₐₓ+Iₘᵢₙ); and the degree of coherence c may be calculated with bright streak light intensity and dark streak light intensity measured by the streak camera after the light radiation passes through a Michelson interferometer set up along the collection light path according to a formula (I_{bright}−I_{dark})/(I_{bright}+I_{dark}).

An upper limit of a coding bandwidth obtained in step 6 may at least reach 0.1 THz.

In step 6, “1” and “0” of binary coding may be defined as follows: for any one or more of the luminous intensity I, the degree of polarization P and the degree of coherence c, within a single code time interval: i) a code value may be defined as “1” when a maximum value thereof is above x; ii) the code value may be defined as “1” when an average value thereof is above x; iii) the code value may be defined as “1” when a time integral sum is above x; or iv) with an artificially set smaller time interval parameter s, a time interval integral having the length of s may be randomly selected within a single code time interval, and the code value may be defined as “1” when a maximum integral value is above x, where x may be an artificially defined value as long as the values of the light radiation parameters in the lasing state and the non-lasing state of the optical structure are distinguishable.

In step 3, an exciting light pulse different in frequency from the original-wavelength light path may be generated along the frequency-doubled light path. The frequency-doubled light path may be used for directly exciting the optical structure. The original-wavelength light pulse may be used for non-linear two-photon absorption to regulate a light emission time envelope of the optical structure. Light pulses of two frequencies may be combined to excite an optical sample to obtain a radiation light pulse time envelope in a double-peak shape. The binary code value “1/0” under the excitation by the light pulse of a single frequency may be extended to ternary code value “2/1/0” by the added light emission time envelope information.

According to the present disclosure, in step 2, the overall light pulse may be excited by a pulse pumping apparatus or an integrated pulse exciting bank. The light pulse can be changed to an electric pulse. The single excitation energy density of each electric pulse may be controlled to be above or below the lasing threshold of the optical structure and have the value of 10⁻¹² to 10⁻³ C/cm². The optical structure may be in the lasing or non-lasing state under corresponding electric pulses. Meanwhile, the starting and ending time of the electric pulses exciting the optical structure may be controlled to control triggering and termination of coding. Moreover, the excitation time of each electric pulse may be controlled to control writing of the time information of a coding sequence, and the excitation pulse time interval of electric pulses may be controlled to realize coding bandwidth control.

### ADVANTAGES OF THE PRESENT DISCLOSURE

1) High degree of discrimination and high degree of identification of different code values may be achieved based on significant differences in radiation field properties of the optical structure between the lasing and non-lasing states.

2) Ultrafast optical coding may be realized based on the property of fast transition between the lasing and non-lasing states of the optical structure. According to the present disclosure, the coding bandwidth may be maximally 0.1 THz, pertaining to the scope of above 10 GHz high-bandwidth coding.

3) The physical parameters, intensity I, degree of polarization P and degree of coherence c, of the radiation light field of the optical structure may conform with bundled feature during the transition of the lasing and non-lasing states. The three parameters may change simultaneously during the transition of the states, providing significantly improved code value reliability, and can be used for error correction of a coding sequence.

4) According to the present disclosure, the light emission process of the light-emitting structure may be actively controlled, and generation of radiation light field carriers and embedding of coding information may be completed simultaneously. In addition, later reading and identification of code value information may be realized. The present disclosure provides both ultrafast encoding and decoding functions.

5) Since the encoding information is written from the source by controlling the generation of the radiation light field carriers according to the present disclosure, with a given feasible coding energy saving solution, the generation of, for example, intensity code value “0” can be realized without injection of energy.

6) The lasing and non-lasing behaviors of the optical structure may be combined with non-linear effects such as two-photon absorption, so that higher-order encoding such as ternary encoding can be realized. Thus, the encoding bandwidth range of the present disclosure can be further extended.

### BRIEF DESCRIPTION OF THE DRAWINGS

FIG. 1 is a schematic diagram of transition of lasing and non-lasing states of microspheres according to an embodiment of the present disclosure.

FIG. 2 is a scanning electron microscope (SEM) image of CsPbBr₃ microspheres according to an embodiment of the present disclosure.

FIG. 3 is a high-resolution transmission electron microscope (TEM) image of CsPbBr₃ microspheres according to an embodiment of the present disclosure.

FIG. 4 is a Fourier transform hologram corresponding to CsPbBr₃ microspheres according to an embodiment of the present disclosure.

FIG. 5 is a schematic diagram of a light path according to an embodiment of the present disclosure.

FIG. 6 is a normalized photoluminescence (PL) spectrum of CsPbBr₃ microspheres at different pumping densities according to an embodiment of the present disclosure.

FIG. 7 is a curve graph of the dependency of degree of linear polarization on energy density according to an embodiment of the present disclosure.

FIG. 8 is a kinetic schematic diagram of perovskite degree-of-polarization coder PL parallel or perpendicular to a linear polarization direction according to an embodiment of the present disclosure.

FIG. 9 is a schematic diagram of a linearly polarized PL spectrum from parallel (full line) to vertical (dotted line) according to an embodiment of the present disclosure.

FIG. 10 is a schematic diagram of single-layer high-bandwidth encoding of degree of polarization with the bandwidth of 0.1 THz according to an embodiment of the present disclosure.

FIG. 11 is a schematic diagram of single-layer high-bandwidth encoding of degree of polarization with the bandwidth of 0.1 THz according to an embodiment of the present disclosure.

FIG. 12 is a schematic diagram of single-layer high-bandwidth encoding of fluorescence intensity according to an embodiment of the present disclosure.

FIG. 13 is a schematic diagram of single-layer high-bandwidth encoding of fluorescence intensity according to an embodiment of the present disclosure.

FIG. 14 is a schematic diagram of code value definition based on degree of polarization and pulse shape information of a perovskite micro-coder according to an embodiment of the present disclosure.

FIG. 15 is a schematic diagram of an effective density range of an 800 nm pump laser device for double-layer encoding according to an embodiment of the present disclosure.

FIG. 16 is a schematic diagram of double-layer encoding of degree of polarization and pulse shape according to an embodiment of the present disclosure.

FIG. 17 is a schematic diagram of double-layer encoding of degree of polarization and pulse shape according to an embodiment of the present disclosure.

### DETAILED DESCRIPTION

The present disclosure will be further described below by a combination of the accompanying drawings and examples.

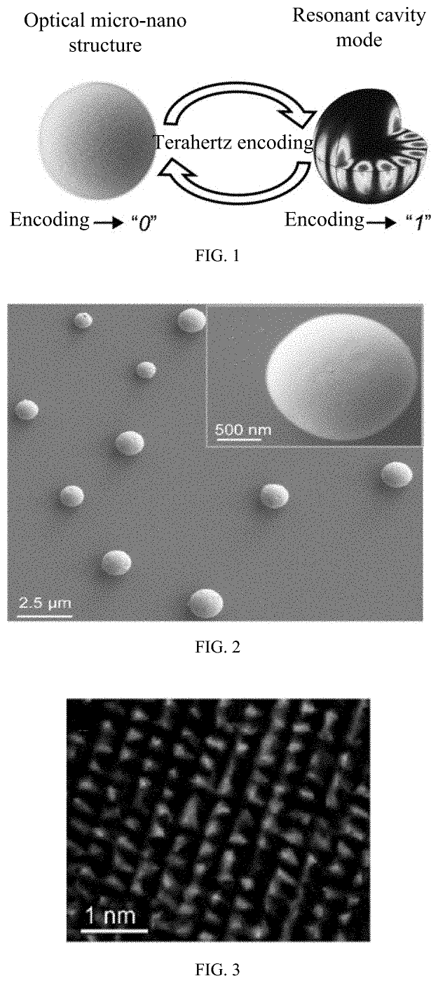

For the convenience of understanding, FIG. 1 is a schematic diagram of transition of lasing and non-lasing states of microspheres according to an embodiment of the present disclosure.

I) Preparation of Microspheres

An optical structure may be grown or prepared by a plurality of micro-nano fabrication techniques. The optical structure may be a light-emitting material or constituted by parts made of a light-emitting material. In some embodiments, the optical structure possesses the characteristic of optical resonant cavity, with optical cavity quality factor Q value of at least 100, solid-state external morphology, and unlimited internal morphology, external shape and chemical compositions of internal and external materials.

In this example, full inorganic cesium lead halide CsPbBr₃ microspheres were prepared as the optical structure by high temperature chemical vapor deposition method.

A horizontal quartz tube furnace with the highest heating temperature of 1200° C., a gas flow controller and a vacuum pump were combined to form a chemical vapor deposition system. A vapor source (˜0.1 g) composed of cesium bromide (CsBr, 99.999% trace metal basis) and lead bromide (PbBr₂, 99.999% trace metal basis) in a molar ratio of 1:1 was used. All reagents were not further purified and directly purchased from Sigma-Aldrich corporation.

Specific preparation process: firstly, the source of CsBr and PbBr₂ was placed at the center of the quartz tube, and a 10*8*0.7 mm silicon slice was placed on a silicone boat. High-purity gas N₂ was guided into the quartz tube at a constant flow rate of 40 sccm. Then, rapid heating was performed to 620° C., and the temperature was held at 620° C. for 20 minutes. Finally, the tube was cooled to room temperature. During the whole process, the pressure in the tube was held at 0.5 Torr.

II) Characterization of Microspheres

FIG. 2 shows the morphological characteristics of the sample, with the CsPbBr₃ microspheres having the diameter of 0.2 to 1.5 μm dispersed on the silicon substrate. The inset is an enlarged SEM image of typical CsPbBr₃ microsphere which has a smooth spherical surface. FIG. 3 shows high-resolution TEM characterization of internal lattice arrangement. Ordered atomic arrangement has proven that CsPbBr₃ microspheres have good crystallinity and low defects. FIG. 4 shows orthorhombic crystal structure of the CsPbBr₃ microspheres indicated by fast Fourier transform. High-quality microspheres can be regarded as a good whispering gallery (WG) microcavity.

The morphology and crystal structure of the prepared CsPbBr₃ microspheres were characterized using Field emission SEM (FE-SEM; Auriga S40, Zeiss, Oberkochen, Germany), high-resolution TEM (HRTEM, JEOL-2010) and X-ray diffraction (XRD, PANalytical Empyrean with CuKα-radiation (λ=1.5418 Å)).

III) Characteristics of Microspheres

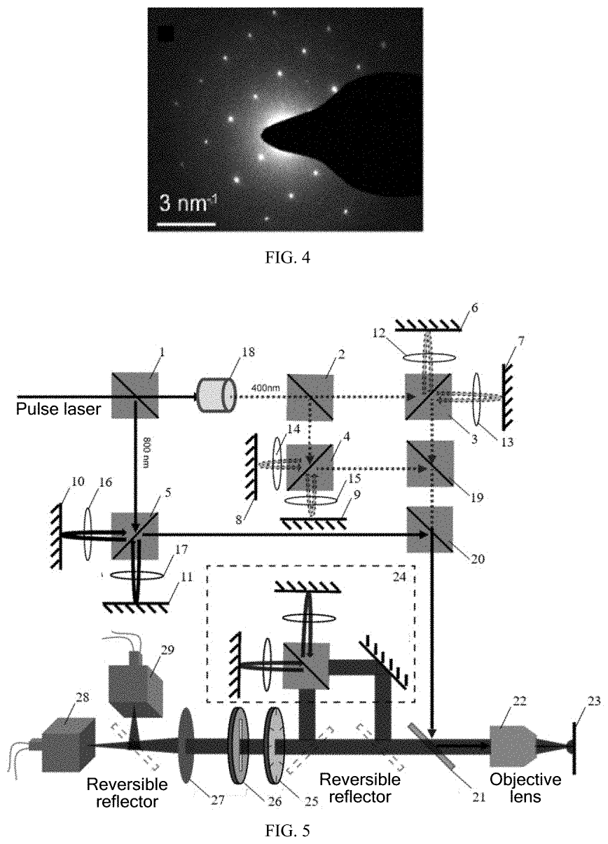

FIG. 5 is a schematic diagram of a light path, based on which the measuring of the characteristics of microspheres and high-bandwidth encoding were performed.

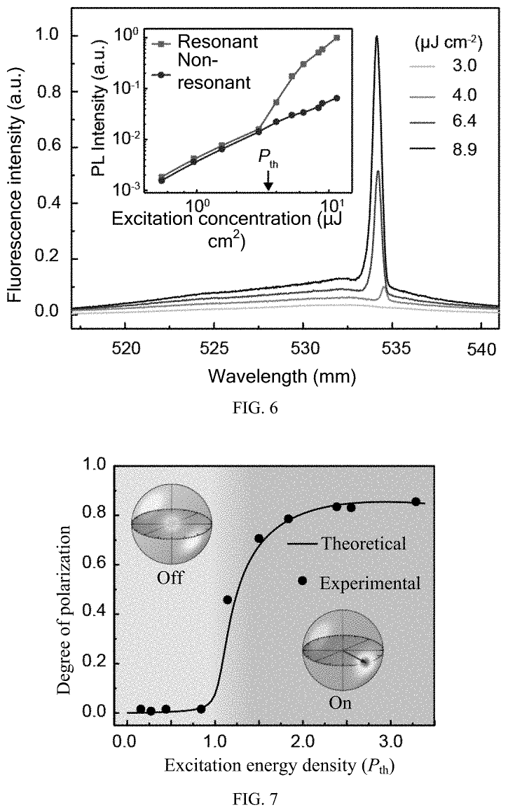

Pulse laser (400 nm, ˜150 fs, 80 Mhz) was used to non-resonantly excite the dispersed CsPbBr₃ microspheres, with energy density-dependent photoluminescence (PL) at 10 k, as illustrated in FIG. 6, the inset showing the dependency of PL intensity on energy density at the resonant cavity wavelength and non-resonant wavelength 535.0 nm. Typical laser behavior was observed from a single CsPbBr₃ microsphere, with a power threshold Pₜₕ as low as about 35 μJ/cm². A single lasing mode occurred at 534.5 nm, and the full width at half maximum (FWHM) was merely 0.5 nm. Compared with the dependency of emission intensity on linear energy density at non-resonant wavelength 535.0 nm, an obvious threshold was shown at the cavity resonant wavelength, indicating a process from spontaneous emission to non-linearly stimulated radiation.

The polarized radiation of a single CsPbBr₃ microsphere was studied under different excitation energy density conditions. Below a laser threshold, no obvious polarization was observed within the whole wavelength range of PL emission. However, above the threshold, the total degree of polarization at the cavity resonant wavelength was approximate to 0.81, with the degree of linear polarization of up to 72%. A sharp and strong peak appeared in a polarization spectrum above the threshold, visually showing high polarization of the stimulated radiation field. Measuring was repeated to obtain the direction of polarization and the degree of polarization, indicating robust and same polarization characteristics of the CsPbBr₃ microspheres. However, these polarization features may be different for different microsphere samples. In addition, the polarization characteristic of a fluorescence signal may not rely on the polarization configuration of non-resonantly excited laser. Even under circularly polarized pumping, linearly polarized laser of CsPbBr₃ microspheres may be established, indicating that high polarization is related to the radiation process of excitons, rather than spin relaxation of carriers, in CsPbBr₃. Negligible polarization in spontaneous fluorescence below the laser threshold may also fit this viewpoint.

The dependency of the degree of polarization on energy was plotted as shown in FIG. 7. Obviously, abrupt change of the degree of polarization occurs at the threshold point, and such anisotropic laser polarization may be attributed to symmetry breaking of the perovskite microsphere cavity and non-linear amplification of the degree of polarization. When the perfect spherical symmetry was broken by uncontrollable fluctuation of synthesis conditions or minimum attachments exposed to the environment during the preparation of the sample, the WG mode may be restricted within the cross section of the regularly rounded and smooth surface, and a higher quality factor (Q value) can be obtained as compared with the mode of elliptical or rough surface. Besides, a standing wave may be formed in the identified planar restricted WG mode, and the Q value of a transverse electric (TE) polarization WG mode may be higher than that of a transverse magnetic (TM) polarization WG mode, where TE/TM denotes that the polarization of an electric field component may be perpendicular/parallel to the restraint plane. Therefore, below a lasing threshold, a high Q value WG mode will exhibit a particular direction of polarization related to the characteristic morphology of the CsPbBr₃ microspheres with no advantage of polarized emission. Compared with non-polarized light field coupling, only a small quantity of radial component may be coupled into the high Q value polarization mode. However, at the threshold, the polarized light field in the high Q value WG mode may be significantly amplified, leading to jump of the degree of polarization.

Based on this characteristic, there is further provided a single CsPbBr₃ microsphere as a light polarization switch, and as shown in FIG. 7, the on/off states of the switch are depicted using a vector in Poincare sphere. Two different radiation states of the CsPbBr₃ microspheres may be defined as two identification states of the light switch. The presence of high degree of polarization may indicate “on” state, and the absence of high degree of polarization (<0.6) may indicate “off” state. The presence or absence of polarization may be reversibly realized by adjusting the excitation density. In addition, this submicron switch may exhibit high on-off contrast and high control sensitivity.

IV) Creation and Function of Light Path

FIG. 5 is a schematic diagram of a light path. A pump pulse for single-layer coding and double-layer coding may be realized by a combination of beam splitters 1-5, frequency doubling crystals 18, adjustable reflectors 6-11 and continuously adjustable attenuators 12-17, and PL signals may be collected in a streak camera or a spectrometer. The dotted box shows a combination of light path elements for studying the coherence of signals by Michelson interference. Polarization information may be detected using a wave plate and a polarizer.

Creation of Overall Light Path

1) Along a laser transmission path from a laser device, a beam of overall light pulse may be divided into several beams of split light pulses using five beam splitters 1-5. Adjustable reflectors 6-11 may be set up at positions directly facing exit surfaces of the beam splitter 3, the beam splitter 4 and the beam splitter 5, and the positions of the reflectors relative to the beam splitters may be adjusted to regulate a time of arrival of each split light pulse at the optical structure and a time interval between different split light pulses.

2) Continuously adjustable attenuators 12-17 may be placed between the beam splitters and the adjustable reflectors. The attenuators may be rotated to control excitation energy density of each split light pulse arriving at the optical structure to be above or below the optical lasing threshold Pₜₕ of the optical structure, where the optical structure may be in lasing state or non-lasing state at corresponding excitation energy densities, respectively. In addition, frequency doubling crystals 18 may be placed along a light path behind the beam splitter 1 to obtain a wavelength-halved light pulse.

3) Different controllable split light pulses may be combined into a beam of light by a beam combiner 19 and a beam combiner 20 for shining on the optical structure 23 placed on a sample stage through the beam splitter 21 and an objective lens 22.

4) A lens 27 and a spectrometer 28 or a streak camera 29 may be arranged at a terminal of the light path to collect light radiation signals within the time of the optical structure being excited by the light pulse, thereby obtaining parameter information in the light radiation signals, where the luminous intensity I may be directly measured by the spectrometer 28; the degree of polarization P may be calculated with maximum and minimum luminous intensities obtained by the spectrometer 28 after rotating a polarizer 26 behind a half-wave plate 25 set up along the collection light path by an angle according to the formula (Iₘₐₓ−Iₘᵢₙ)/(Iₘₐₓ+Iₘᵢₙ); and the degree of coherence c may be calculated with bright streak light intensity and dark streak light intensity measured by the streak camera after the light radiation passes through a Michelson interferometer 24 set up along the collection light path according to the formula (I_{bright}−I_{dark})/(I_{bright}+I_{dark}).

Referring to the light paths as shown by the dotted lines in FIG. 5, excessively long pulse time interval of the initial overall pulse from a femtosecond laser device may be adverse to rapid regulation and obtaining of single pulses different in power. The overall pulse may be divided into any number of split pulses using several beam splitters, and a single split pulse adjustable in time delay can be generated with one beam splitter in combination with one distance adjustable reflector. In other words, the time of incidence of a split pulse on the optical structure may be controlled by controlling the distance; meanwhile, the transmission power of this split pulse can be controlled by an attenuator added in the light path, and hence, the energy density of the split beam incident on the optical structure may be naturally regulated. Finally, these beams of light that can be regulated separately may be combined into a single beam by the beam combiners to excite the same point on the optical structure.

Hence, the starting and ending time of the light pulse exciting the optical structure may be controlled to control triggering and termination of coding. The position of each adjustable reflector may be adjusted to control the excitation time of each split pulse, thereby controlling writing of time information of a coding sequence; meanwhile, the time interval of excitation pulses may be controlled to control the coding bandwidth. Thus, writing of the coding sequence may be completed. Time parameter τ_{rad} may be full width at half maximum when the optical structure operates in the lasing state. Writing of coding can be achieved only when the requirements of the full width at half maximum of the overall light pulse of at most τ_{rad}/2 and adjustable pulse interval time of at least τ_{rad} are satisfied.

The collection light path may be created using other optical elements such as the objective lens, the lens, the spectrometer and the streak camera, so that light radiation signals of the optical structure within the coding time can be collected. Identification of coding can be realized only at detection time accuracy of 1/10 of the full width at half maximum τ_{rad} of a single light radiation pulse. A lot of parameter information may be extracted from the light radiation signals, with “1/O” denoting the parameter information in the lasing/non-lasing state, and one or more of extracted parameters may be used to identify and check a coding sequence.

V) Method of Single-Layer High-Bandwidth Coding of Degree of Polarization Based on Lasing-Non-Lasing State Transition of Microspheres

Pulse laser may resonantly or non-resonantly excite the dispersed optical structure, and energy density dependent fluorescence spectrum may be measured in a low-temperature environment. Typical lasing behavior may be observed from a single structure, with a lasing power threshold below the existing general level and a single lasing mode occurring at the resonant wavelength.

The laser duration of the optical structure is τ_{rad}, reduced by two orders of magnitude as compared with that of spontaneous emission. Highly strong fluorescence signals may be collected within very short time in the direction of linear polarization, only extremely weak fluorescence signals can be obtained in a direction perpendicular to the direction of linear polarization. This means that highly linear polarization is concentrated in very short time. Coding of the degree of polarization may be realized based on the accelerated radiation behavior in the stimulated amplification process. Here, coder “1/0” means that the degree of polarization of the radiation field is above/below a defined value within a corresponding coding duration, and the degree of polarization in the non-lasing state may be below the value. A high degree of polarization may be accompanied by a strong laser signal, providing a high resolution. Other parameters such as light intensity I or degree of coherence c of radiation in the lasing/non-lasing state may be defined and collected like the degree of polarization P, so that high-bandwidth single-layer coding can be realized like the degree of polarization P, and other parameters not used for code value identification may be used for check or error correction of the coding information.

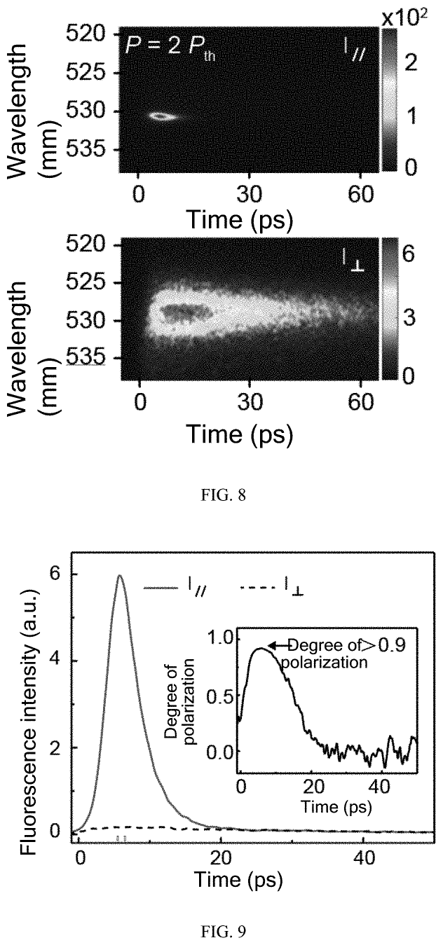

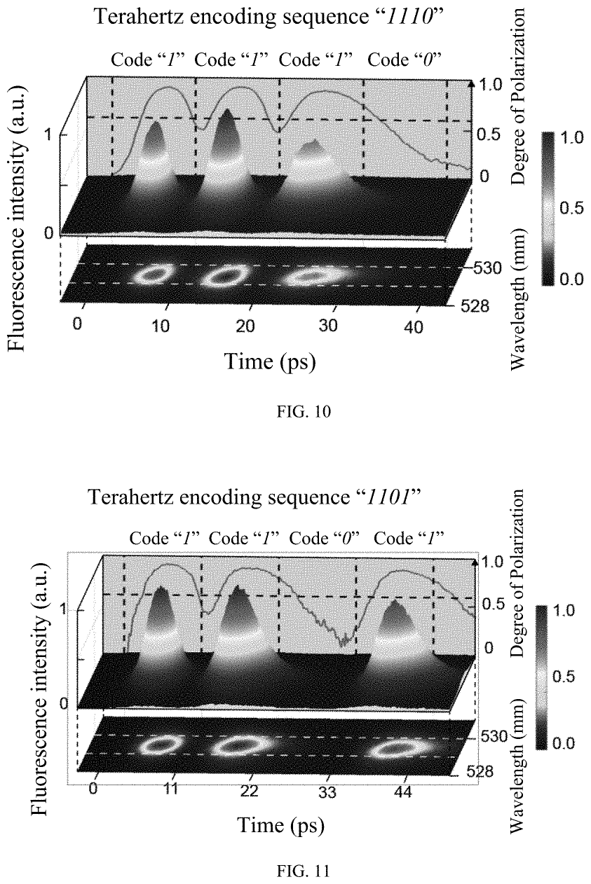

In this example, the laser duration of the CsPbBr₃ microspheres was ˜5 ps, reduced by two orders of magnitude as compared with that of spontaneous emission, and highly strong fluorescence signals could be collected within very short time in the direction of linear polarization, while only extremely weak fluorescence signals could be obtained in the direction perpendicular to the direction of linear polarization, as illustrated in FIG. 8. This means that highly linear polarization was concentrated in very short time, as illustrated in FIG. 9. The coding of the degree of polarization could be realized based on the accelerated radiation behavior in the stimulated amplification process, as shown by high-bandwidth coding in FIG. 10 and FIG. 11. Here, coder “1/0” was defined as that the degree of polarization of the radiation field was above/below 0.6 within the corresponding coding duration. The high degree of polarization was accompanied by the strong laser signal, providing the high resolution. The input information of the coding sequence was written to the perovskite coder. The output bandwidth of the coder may be adjusted and the upper limit thereof may be approximately 1 THz, depending on the laser duration of the microstructure of the perovskite.

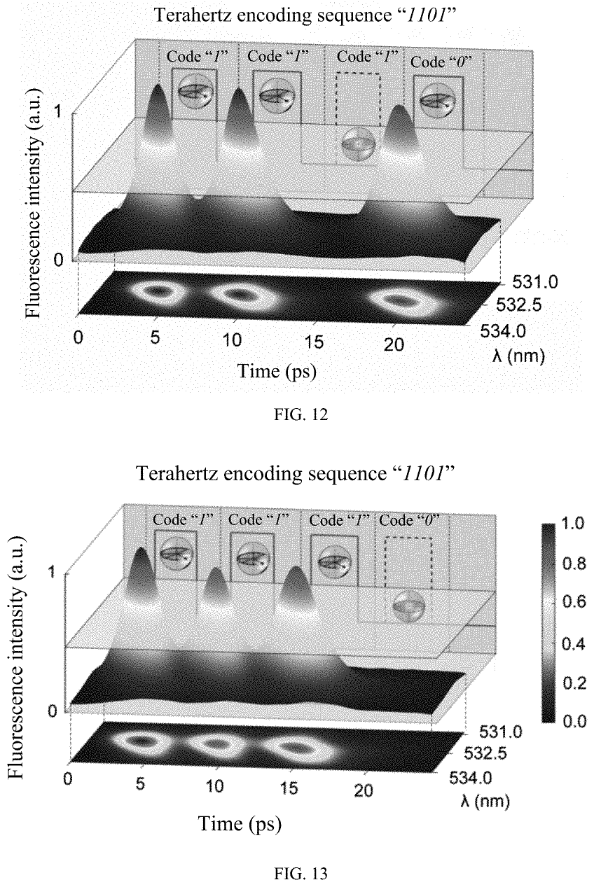

Similarly, other parameters (e.g., fluorescence intensity) of output radiation can be defined for coding. For example, FIG. 12 and FIG. 13 show single-layer high-bandwidth coding of fluorescence intensity based on lasing-non-lasing state transition of microspheres, where the coding bandwidth reached 0.2 THz.

VI) Method of Double-Layer High-Bandwidth Coding of Degree of Polarization and Pulse Shape Based on Transition of Lasing State and Non-Lasing State of Optical Structure

Referring to the light paths as shown by the dotted lines and the full lines in FIG. 5, other parameters such as time-correlated shape of the laser pulse may also be used to encode information. Two types of coding information may be written to the optical structure using two pulses having different lengths, and writing to the degree-of-polarization coder may be achieved still by the original pulse. Another femtosecond pulse light beam may be introduced for coding of shape, and the pulse may have a wavelength twice that of the original pulse and be adjustable in power. Therefore, a double-peak shape can appear in the radiation pulses of the optical structure collected after excitation by the additional pulse along with the original pulse. To effectively modulate the laser shape, there may be a certain usable time interval range between the two pulses, depending on τ_{rad}. Because of the transient response of the pulse shape, new coding information about the pulse shape may be combined with the previously realized high-bandwidth coding. Coding based on the degree of polarization or other parameter may be referred to as single-layer coding, and compiling of two pieces of independent information layer by layer may be referred to as double-layer coding. In multi-layer coding, additional pulse shape information may be written on “1” into “2”, while writing without pulse shape information may lead to unchanged “1”. Due to impossible writing on “0”, the definition of “2/1/0” can be ultimately realized, allowing for high-bandwidth double-layer coding.

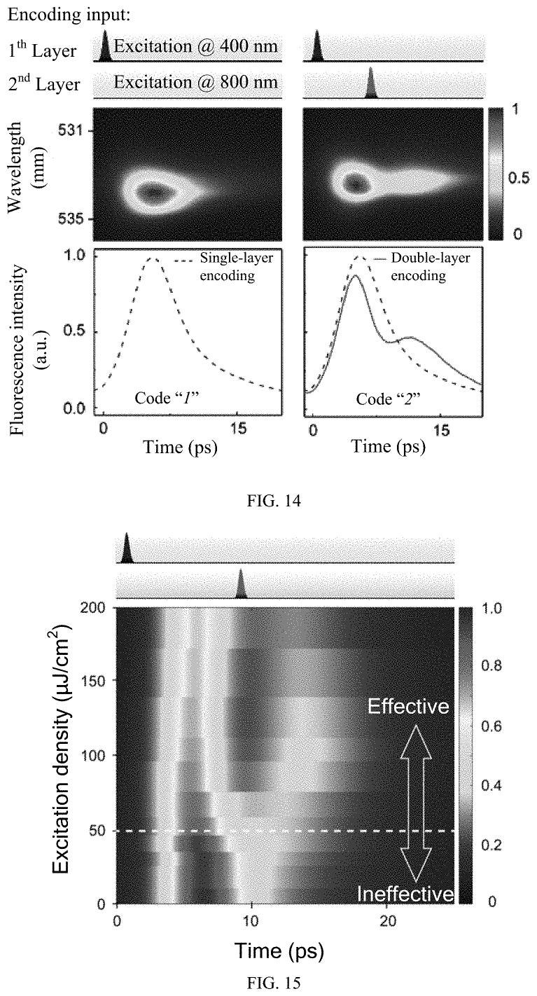

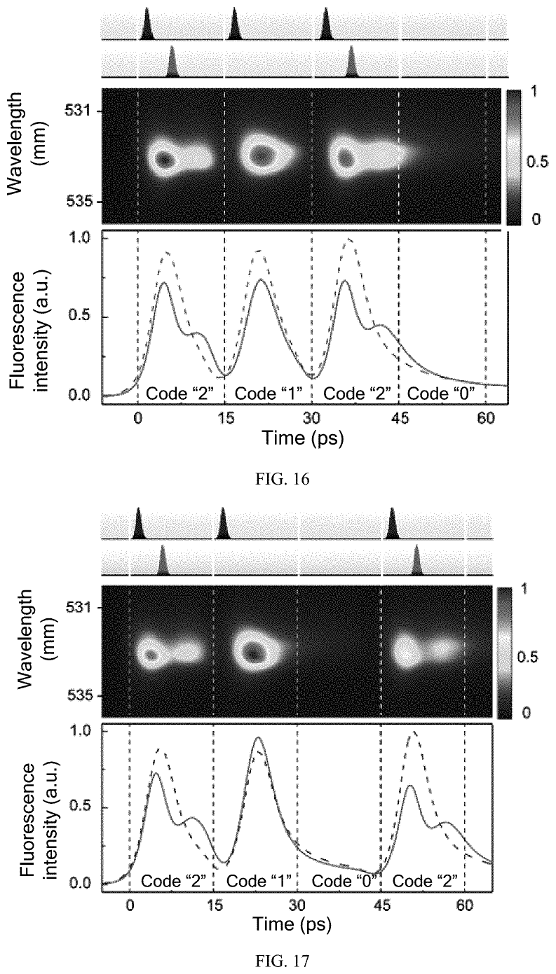

In this example, apart from the parameter degree of polarization, other parameter such as the time-correlated shape of the laser pulse was used as the coding information. Two pump light beams having different wavelengths were used to write two types of coder information to the CsPbBr₃ microspheres. Writing to the degree-of-polarization coder was performed still by 400 nm pump light beam, as illustrated in FIG. 14. Another femtosecond pulse light beam having the wavelength of 800 nm (˜75 μJ/cm²) was introduced for coding of shape. Strong 800 nm light beam could produce obvious two-photon absorption effect. The effective density range of the 800 nm pulse for coding of shape was studied, as illustrated in FIG. 15. When the pump density was above 50 μJ/cm², obvious modulation of PL shape was realized. Here, shape modulation was attributed to carriers excited by non-linear absorption and direct absorption of the 800 nm pump pulse. Low-energy state carriers excited by direct absorption could be scattered along with excitons and enhance the non-radiative recombination of excitons. Therefore, the laser intensity was first reduced after the addition of the 800 nm pulse. However, high-energy carriers excited by two-photon absorption would provide an exciton storage layer after transient energy relaxation process and contribute additional release afterwards. Therefore, the double-peak shape appeared in the laser pulse at the moment of embedding. To effectively modulate the laser shape, the usable time interval range between the two pulses was 5-10 ps. In addition, slight blue shift of PL energy under the excitation by the light beams of two wavelengths was mainly attributed to the carriers excited by direct absorption of the 800 nm laser. Because of the transient response of the pulse shape, the shape information could be combined with a high-bandwidth coding sequence, with new code denoted by “2” different from the undefined code “1/0”. Therefore, two pieces of different information (degree of polarization and shape) could be embedded into the perovskite coder layer by layer to realize double-layer coding. FIG. 16 and FIG. 17 illustrate different double-layer code sequences “2120” and “2102”, respectively, with dotted lines denoting single-layer code sequences “1110” and “1101” for comparison.

PL spectrum and dynamic measuring: the CsPbBr₃ microspheres were placed in closed-loop high vacuum Dewar (MONTANA) for all optical experiments at the temperature of 10 K. By second harmonic generation (SHG) process, an excitation source of 800 nm femtosecond laser (150 fs, 80 MHz) and 400 nm femtosecond laser was used. All PL signals were collected by 50× objective lens (NA=0.55) in a confocal fluorescence detection system. PL was measured by a spectrometer (ANDOR, Newton, SR500i). Time dynamic measurements were analyzed by a streak camera (Hamamatsu, C10910).

The above described examples merely present one embodiment of the present disclosure, which is described specifically and in detail, but cannot be hereby construed as limiting the scope of the present disclosure. While the optical structure used in the examples is the micro-nano structure of perovskite microspheres, suitable optical structures in the present disclosure are not necessarily micro-nano structures. It should be noted that various variations and improvements can be made by one of ordinary skill in the art without departing from the concept of the present disclosure and are within the protection scope of the present disclosure.

What is claimed is:

1. A method of coding based on transition of lasing and non-lasing states of an optical structure, comprising the following specific steps:
step 1: selecting an optical structure which is a light-emitting material or constituted by parts made of a luminous material and possesses the characteristic of optical resonant cavity, with optical cavity quality factor Q value of at least 100 and unlimited chemical composition of the material, and placing the optical structure on a sample stage;
step 2: along a laser transmission path of a laser device, dividing a beam of overall light pulse into several beams of split light pulses using several beam splitters, setting up adjustable reflectors at positions directly facing exit surfaces of the beam splitters, and adjusting the positions of the reflectors relative to the beam splitters to regulate a time of arrival of each split light pulse at the optical structure and a time interval between different split light pulses;
step 3: placing continuously adjustable attenuators between the beam splitters and the adjustable reflectors, rotating the attenuators to control excitation energy density of each split light pulse arriving at the optical structure to be above or below an optical lasing threshold Pₜₕ of the optical structure, wherein the optical structure is in the lasing state or the non-lasing state at corresponding excitation energy densities, respectively; and placing frequency doubling crystals along a light path behind a first beam splitter to obtain a wavelength-halved light pulse, wherein the light path is called a frequency-doubled light path, an original-wavelength light pulse is retained along another light path;
step 4: combining different controllable split light pulses into a beam of light by beam combiners for shining on the optical structure placed on the sample stage through a beam splitter and an objective lens, thereby realizing embedding of optical code information, wherein an induced radiation light field of the optical structure carries a high-bandwidth coding sequence;
step 5: arranging a lens, a spectrometer and a streak camera at a terminal of the light path to collect light radiation signals within the time of the optical structure being excited by the light pulse, thereby obtaining parameter information, namely luminous intensity I, degree of polarization P and degree of coherence c, in the light radiation signals; and
step 6: defining that one or more of the obtained light radiation signal parameters in the lasing state and the non-lasing state correspond to “1” and “0” of binary coding, respectively, and reading or checking an optical coding sequence generated in this period of light pulse excitation time using the spectrometer and the streak camera.

2. The method according to claim 1, wherein in step 2, the full width at half maximum of the overall light pulse is at most τ_{rad}/2, and time parameter τ_{rad} is the full width at half maximum of the light radiation pulse when the optical structure operates in the lasing state, with adjustable pulse interval time of at least τ_{rad}.

3. The method according to claim 1, wherein in step 2, the regulating of the time interval between different split light pulses is to change each split light propagation path to realize time delays of different split light pulses.

4. The method according to claim 1, wherein in step 3, the optical lasing threshold Pₜₕ depends on the selected optical structure and has a value of 10⁻⁹ to 1 J/cm².

5. The method according to claim 1, wherein in step 3, a maximum energy density from the split pulses into the optical structure at least reaches Pₜₕ.

6. The method according to claim 1, wherein in step 5, the detection time accuracy of the streak camera is at least ⅓ of the full width at half maximum τ_{rad} of a single light radiation pulse.

7. The method according to claim 1, wherein in step 5, the luminous intensity I is directly measured by the spectrometer and the streak camera; the degree of polarization P is calculated with maximum and minimum luminous intensities obtained by the spectrometer and the streak camera after rotating a polarizer set up along a collection light path according to a formula (Iₘₐₓ−Iₘᵢₙ)/(Iₘₐₓ+Iₘᵢₙ); and the degree of coherence c is calculated with bright streak light intensity and dark streak light intensity measured by the streak camera after the light radiation passes through a Michelson interferometer set up along the collection light path according to a formula (I_{bright}−I_{dark})/(I_{bright}+I_{dark}).

8. The method according to claim 1, wherein an upper limit of a coding bandwidth obtained in step 6 at least reaches 0.1 THz.

9. The method according to claim 1, wherein in step 6, “1” and “0” of binary coding are defined as follows: for any one or more of the luminous intensity I, the degree of polarization P and the degree of coherence c, within a single code time interval: i) a code value is defined as “1” when a maximum value thereof is above x; ii) the code value is defined as “1” when an average value thereof is above x; iii) the code value is defined as “1” when a time integral sum is above x; or iv) with an artificially set smaller time interval parameter s, a time interval integral having the length of s is randomly selected within a single code time interval, and the code value is defined as “1” when a maximum integral value is above x, wherein x is an artificially defined value as long as the values of the light radiation parameters in the lasing state and the non-lasing state of the optical structure are distinguishable.

10. The method according to claim 1, wherein in step 3, an exciting light pulse different in frequency from the original-wavelength light path is generated along the frequency-doubled light path; the frequency-doubled light path is used for directly exciting the optical structure; the original-wavelength light pulse is used for non-linear two-photon absorption to regulate a light emission time envelope of the optical structure; light pulses of two frequencies are combined to excite an optical sample to obtain a radiation light pulse time envelope in a double-peak shape; and the binary code value “1/0” under the excitation by the light pulse of a single frequency is extended to ternary code value “2/1/0” by the light emission time envelope information.
